(19) United States
(12) Patent Application Publication
(10) Pub. No.: US 2009/0261817 A1
(43) Pub. Date: Oct. 22, 2009

(54) TEST HANDLER, METHOD OF UNLOADING AND MANUFACTURING PACKAGED CHIPS AND METHOD FOR TRANSFERRING TEST TRAYS

(76) Inventors: Hee Rak Beom, Seoul (KR); Kyeong Tae Kim, Suwon-Si (KR)

Correspondence Address: KED & ASSOCIATES, LLP, P.O. Box 221200, Chantilly, VA, 20153-1200, US

(21) Appl. No.: 12/339,959

(22) Filed: Dec. 19, 2008

(30) Foreign Application Priority Data
Apr. 21, 2008 (KR) 10-2008-0036582

(51) Int. Cl. G01R 31/28

(52) U.S. Cl. 324/158.1

(57) ABSTRACT

A test handler, a method for unloading packaged chips, a method for transferring test trays, and a method for manufacturing packaged chips are provided. The test handler may include: a loading unit having a loading picker to perform a loading process on a test tray located at a loading position, a chamber system in which the packaged chips contained in the test tray transferred from the loading unit are connected to a hi-fix board and tested, and an unloading unit having at least one unloading buffer to move along an unloading moving path formed over a test tray located at an unloading position and an unloading picker to perform an unloading process on the test tray located at the unloading position. The test handler may further include a passage site disposed between the loading unit and the unloading unit and connecting the loading unit and the unloading unit to the chamber system, and a transferring unit transferring the test trays.

### BACKGROUND

1. Field

Embodiments of the present invention may relate to a test handler for connecting packaged chips to be tested to a tester and classifying packaged chips tested by the tester by grades based on the test result.

2. Background

A test handler may perform electrical tests on packaged chips at a conclusion of a packaging process.

The test handler may be connected to a particular tester for testing packaged chips. The tester may include a hi-fix board in which a plurality of test sockets to which the packaged chips are connected are arranged. The hi-fix board may be coupled to the test handler.

The test handler may perform a loading process, an unloading process, and a testing process by use of a test tray including a plurality of containing units that contain the packaged chips.

The test handler may perform the loading process. The packaged chips to be tested in a user tray may be transferred from the user tray to a test tray in the loading process.

The test handler may perform the testing process. The packaged chips contained in the test tray in the loading process may be connected to test sockets in the testing process. The tester may test the packaged chips connected to the hi-fix board to determine whether the packaged chips operate normally.

The test handler may include a plurality of chambers for heating or cooling the packaged chips to determine whether the packaged chips operate normally under high temperature, low temperature and normal temperature.

The test handler may perform the unloading process. The packaged chips tested in the testing process may be transferred from the test tray to the user tray in the unloading process. The test handler contains the tested packaged chips in the corresponding user trays by grades based on the test result.

More packaged chips may be manufactured for a short amount of time by reducing a time for the loading process, the testing process, and the unloading process, thereby strengthening competitive power of products such as cost reduction.

### BRIEF DESCRIPTION OF THE DRAWINGS

Arrangements and embodiments may be described in detail with reference to the following drawings in which like reference numerals refer to like elements and wherein:

FIG. 1 is a plan view schematically illustrating a test handler according to an example embodiment of the present invention;

FIG. 2 is a perspective view schematically illustrating a loading unit and an unloading unit;

FIGS. 3A to 3D are side views schematically illustrating an example where a loading buffer and a loading picker operate;

FIGS. 4A to 4D are side views schematically illustrating another example where the loading buffer and the loading picker operate;

FIG. 5 is a diagram schematically illustrating a path through which a test tray is transferred between a loading unit, a passage site, and an unloading unit;

FIG. 6 is a front view schematically illustrating a loading unit, an unloading unit, and a passage site;

FIGS. 7A to 7D are side views schematically illustrating an example where an unloading buffer and an unloading picker operate;

FIGS. 8A to 8D are side views schematically illustrating another example where an unloading buffer and an unloading picker operate;

FIG. 9 is a plan view schematically illustrating a loading unit and an unloading unit;

FIG. 10 is a diagram schematically illustrating a path through which a test tray is transferred in a test handler according to an example embodiment of the present invention; and

FIGS. 11 and 12 are perspective views schematically illustrating a transferring unit of a test handler according to an example embodiment of the present invention.

### DETAILED DESCRIPTION

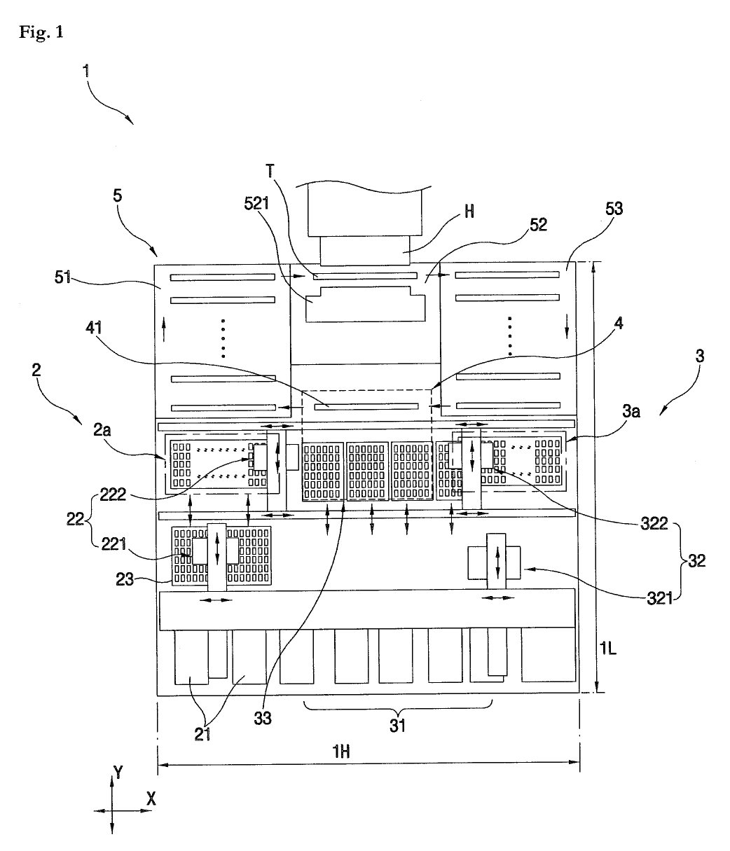

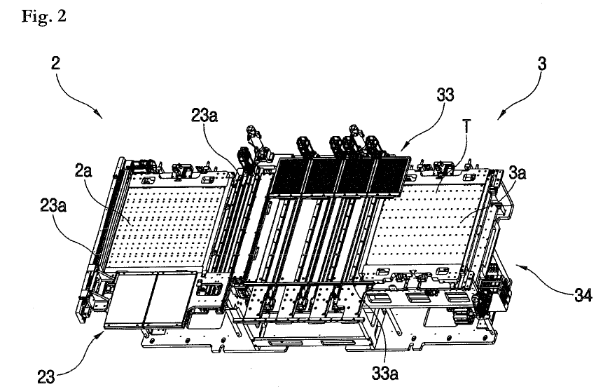

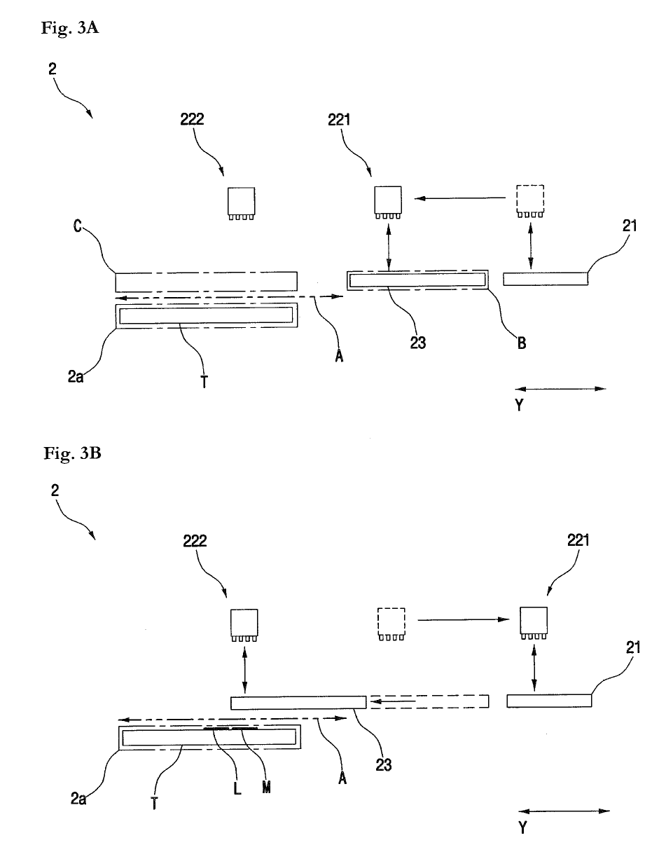

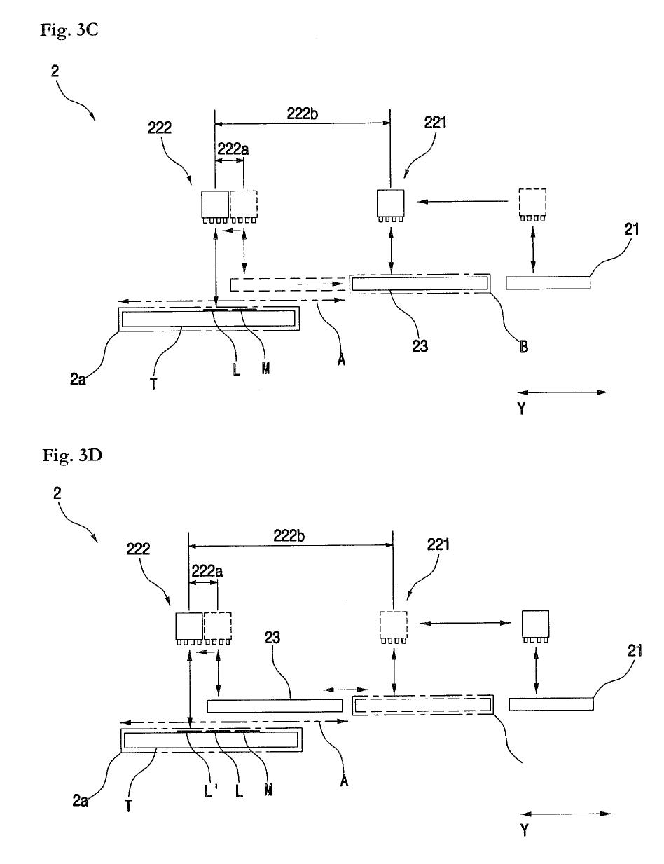

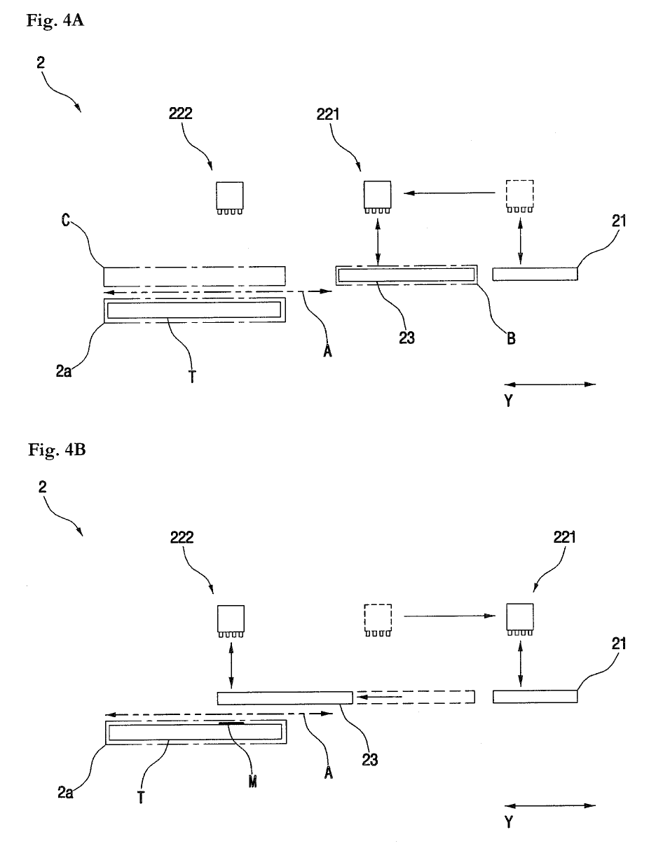

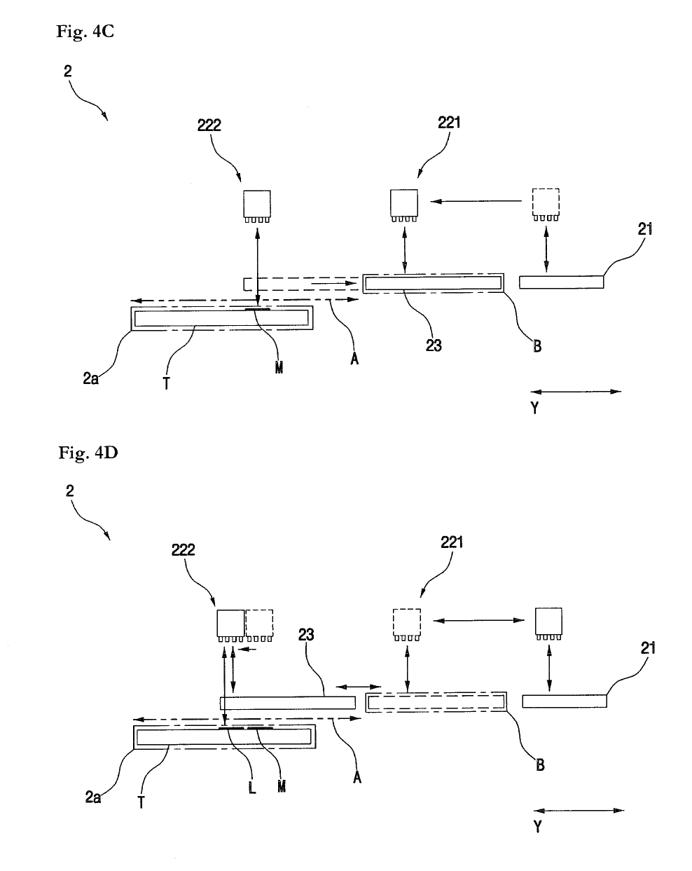

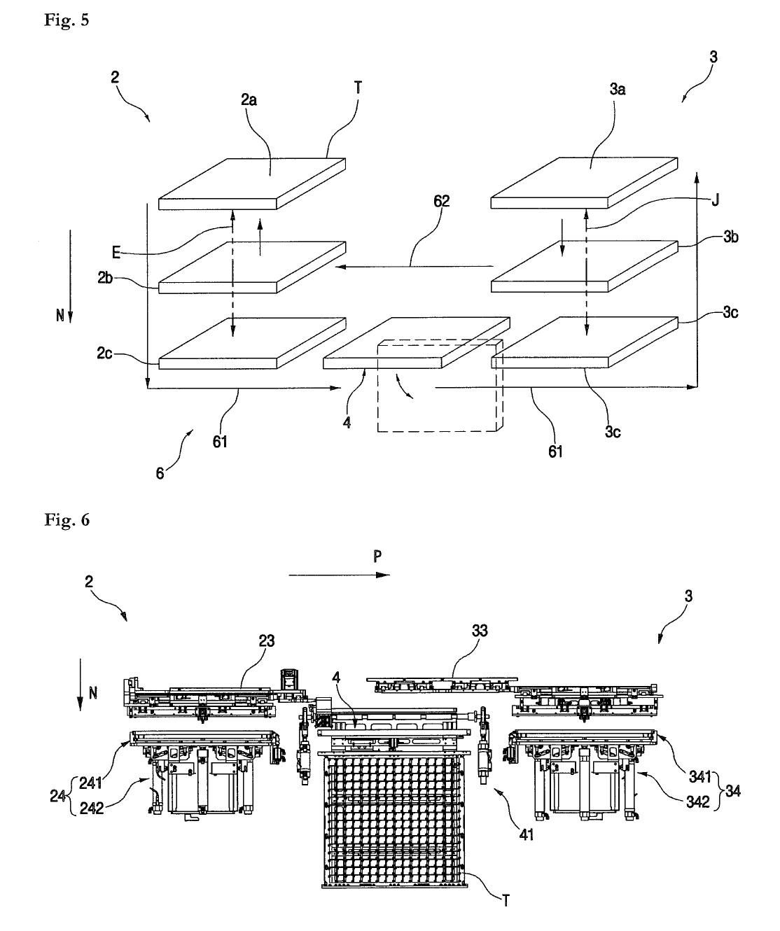

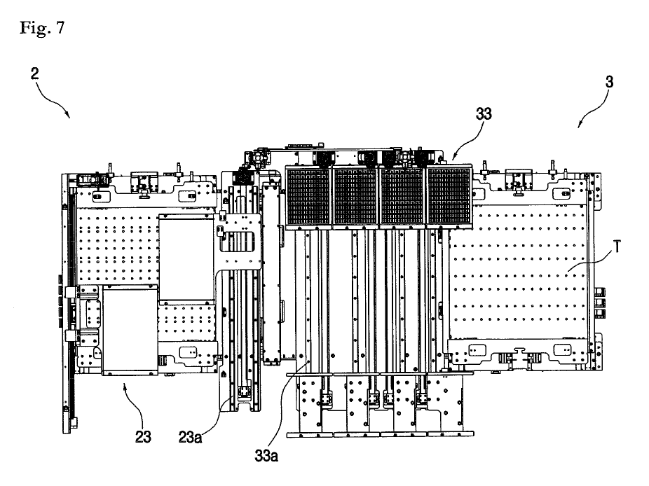

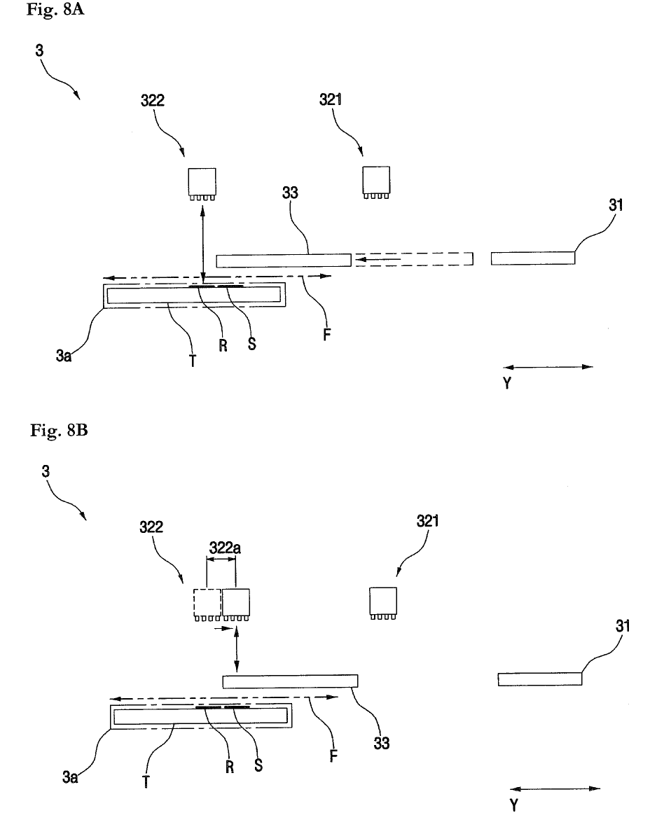

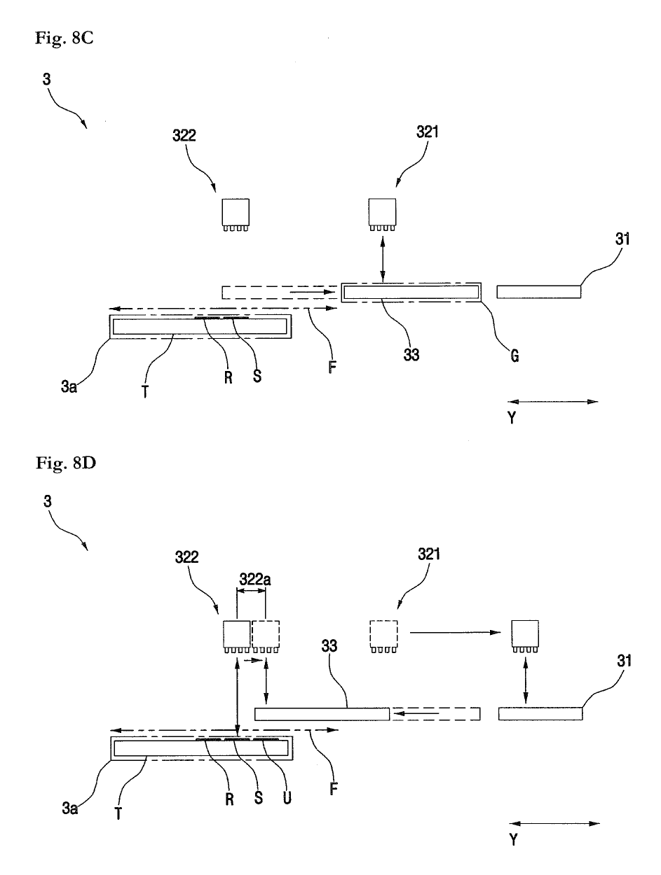

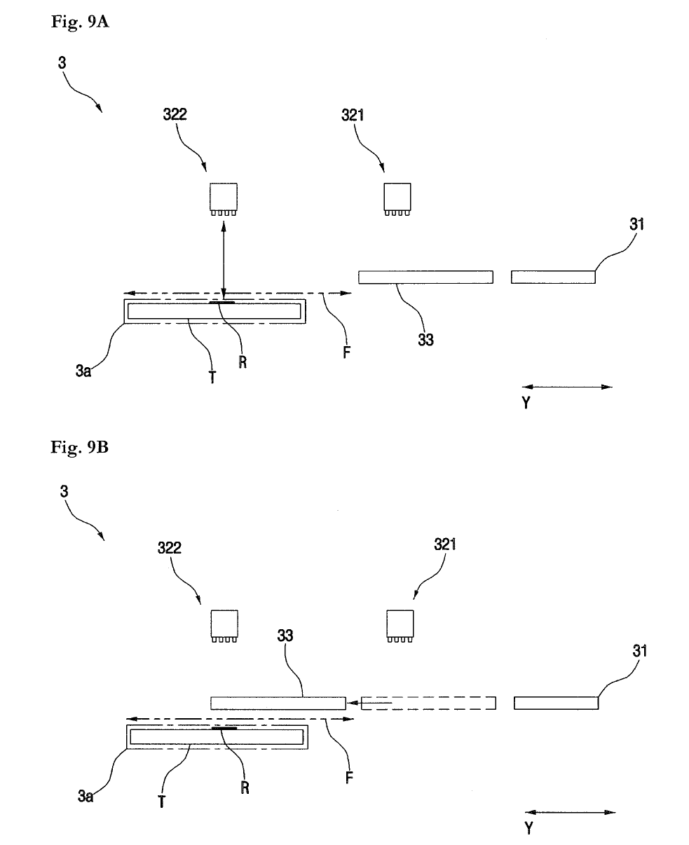

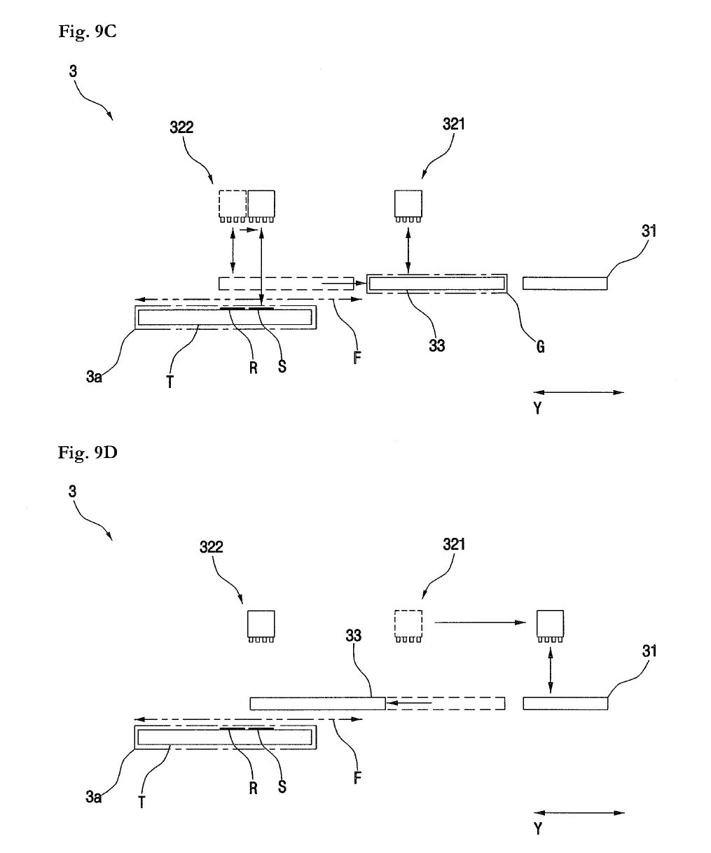

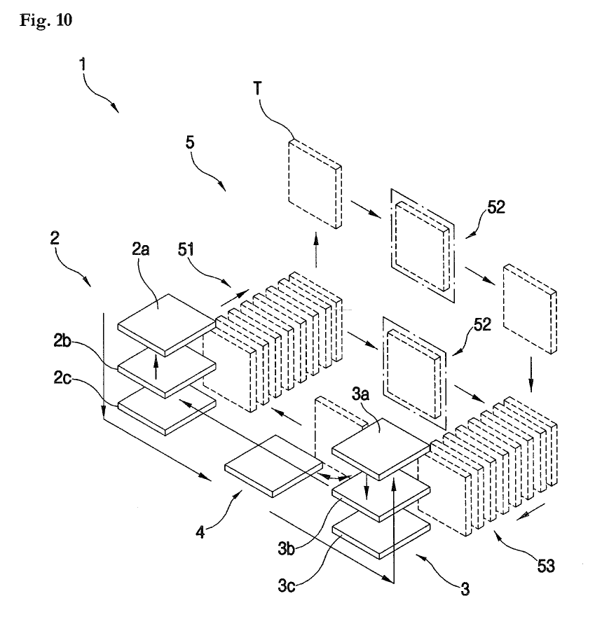

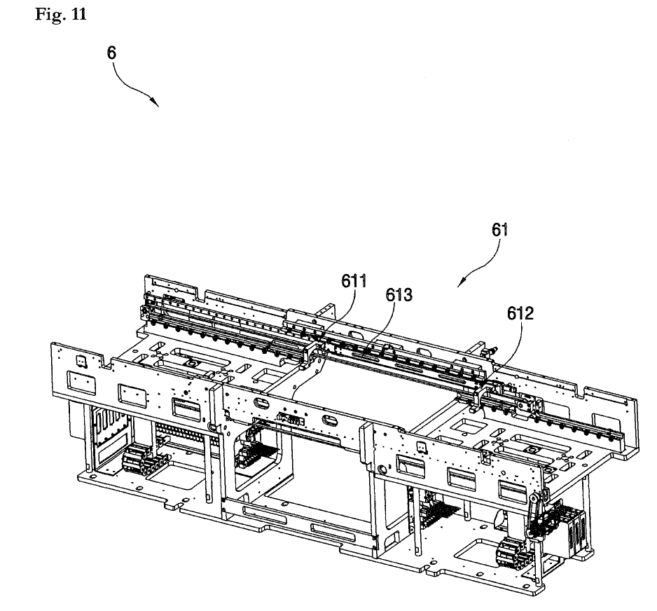

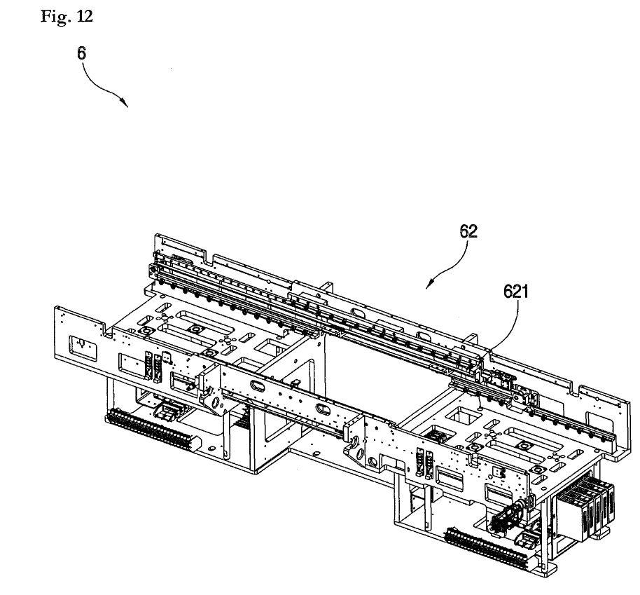

FIG. 1 is a plan view schematically illustrating a test handler according to an example embodiment of the present invention. FIG. 2 is a perspective view schematically illustrating a loading unit and an unloading unit. FIGS. 3A to 3D are side views schematically illustrating an example where a loading buffer and a loading picker operate. FIGS. 4A to 4D are side views schematically illustrating another example where the loading buffer and the loading picker operate. FIG. 5 is a diagram schematically illustrating a path through which a test tray is transferred between a loading unit, a passage site, and an unloading unit. FIG. 6 is a front view schematically illustrating a loading unit, an unloading unit, and a passage site. FIGS. 7A to 7D are side views schematically illustrating an example where an unloading buffer and an unloading picker operate. FIGS. 8A to 8D are side views schematically illustrating another example where an unloading buffer and an unloading picker operate. FIG. 9 is a plan view schematically illustrating a loading unit and an unloading unit. FIG. 10 is a diagram schematically illustrating a path through which a test tray is transferred in the test handler according to an example embodiment of the present invention. FIGS. 11 and 12 are perspective views schematically illustrating a transferring unit of a test handler according to an example embodiment of the present invention.

Reference numerals denoting test trays in FIGS. 5 and 10 may indicate elements of a test handler in which the test trays are located. The test trays drawn by dotted lines in FIG. 10 may indicate a transferring path of the test trays transferred in a passage site and a chamber system and the test trays drawn by solid lines may indicate a transferring path of the test trays transferred among a loading unit, a passage site, and an unloading unit.

As shown in FIG. 1, a test handler 1 may include a loading unit 2, an unloading unit 3, a passage site 4, a chamber system 5, and a transferring unit 6 (as shown in FIGS. 11 and 12).

The loading unit 2 may perform a loading process and include a loading stacker 21, a loading picker 22, and a loading buffer 23.

The loading stacker 21 may store a plurality of user trays each containing packaged chips to be tested.

The loading picker 22 may perform the loading process on a test tray T. The test tray T may be located at a loading position 2a at a time of containing the packaged chips to be tested in the test tray.

The loading picker 22 may move along (or in) an X axis direction and a Y axis direction and may ascend and descend. The loading picker 22 may include nozzles for sucking and attaching (or fixing) to the packaged chips. The loading picker 22 may include a first loading picker 221 and a second loading picker 222.

The first loading picker 221 may pick up the packaged chips to be tested from a user tray located in the loading stacker 21 and may contain the picked-up packaged chips in the loading buffer 23. The test handler 1 may include a plurality of loading pickers 221.

The first loading picker 221 may pick up the plurality of packaged chips (in a unit of a matrix) from the user tray located in the loading stacker 21 at a same time and can provide the picked-up packaged chips in the loading buffer 23 (in the unit of the matrix) at a same time.

The second loading picker 222 may pick up the packaged chips to be tested from the loading buffer 23 and may contain the picked-up packaged chips in the test tray T located at the loading position 2a. The test handler 1 may include a plurality of second loading pickers 222.

The second loading picker 222 may partition the test tray T located at the loading position 2a into a plurality of containing areas and contain the packaged chips to be tested in the containing areas.

The containing area may be in a matrix unit formed by the packaged chips that the second loading picker 222 can contain in the test tray T at a same time. That is, the containing area may be a matrix unit formed by the plurality of packaged chips that can be sucked and attached at a same time by the second loading picker 222.

The second loading picker 222 may pick up a plurality of packaged chips from the loading buffer 23 in the unit of the matrix at a same time and can contain the picked-up packaged chips in the test tray T in the unit of the matrix at a same time.

As shown in FIGS. 1 and 2, the loading buffer 23 can move in the Y axis direction and can temporarily contain the packaged chips to be tested. The loading buffer 23 may move in the X axis direction and the Y axis direction. The test handler 1 may include at least one loading buffer 23.

Although not shown, the loading buffer 23 may be coupled to a belt that connects a plurality of pulleys to move when a motor rotates at least one pulley. When the test handler 1 includes a plurality of loading buffers 23, the loading buffers 23 may each move individually.

Referring to FIGS. 2 and 3A, the loading buffer 23 may move along a loading moving path A formed over the loading position 2a. The loading buffer 23 can move along the loading moving path A and pass over the test tray T located at the loading position 2a.

The loading buffer 23 may move along the loading moving path A and may be located in an area (i.e., an area B in FIG. 3A) between the user tray located in the loading stacker 21 and the loading position 2a or the loading buffer 23 may be located in an area (i.e., an area C in FIG. 3A) above the test tray T located at the loading position 2a.

The loading buffer 23 may be movably coupled to a loading guide rail 23a to guide the loading buffer 23 along the loading moving path A.

The loading buffer 23 may pass over the test tray T located at the loading position 2a, thereby reducing a distance by which the second loading picker 222 moves to perform the loading process. That is, the loading buffer 23 moves along the loading moving path A to reduce a distance by which the second loading picker 222 moves at the time of performing the loading process.

Therefore, the time for the loading process may be reduced and efficiency of the loading process may be enhanced.

An example where the loading buffer 23 and the loading picker 22 operate may now be described with reference to FIGS. 3A to 3D.

In this embodiment, the loading buffer 23 may move along the loading moving path A to transfer the packaged chips to be tested to another containing area that is adjacent to a containing area where the second loading picker 222 should contain the packaged chips to be tested in the test tray T located at the loading position 2a.

As shown in FIG. 3A, when the loading buffer 23 is located in an area (i.e., the area B) between the user tray located in the loading stacker 21 and the loading position 2a, the first loading picker 221 may provide the packaged chips to be tested to the loading buffer 23. After the packaged chips to be tested are contained in the loading buffer 23, the loading buffer 23 may move along the loading moving path A.

As shown in FIG. 3B, the loading buffer 23 may transfer the packaged chips to be tested to another containing area M that is adjacent to the containing area L where the second loading picker 222 contains the packaged chips to be tested in the test tray T located at the loading position 2a.

As shown in FIG. 3C, the second loading picker 222 may pick up the packaged chips to be tested from the loading buffer 23, move to the corresponding containing area L by a predetermined distance 222a, and then contain the picked-up packaged chips in the test tray T located at the loading position 2a.

Accordingly, the second loading picker 222 may move the distance 222a, which is less than the moving distance 222b, when the loading buffer 23 is located in the area (i.e., the area B) between the user tray located in the loading stacker 21 and the loading position 2a and perform the loading process. As a result, a time for the loading process may be reduced.

The loading buffer 23 may move to the area (i.e., the area B) between the user tray located in the loading stacker 21 and the loading position 2a while the second loading picker 222 containing the packaged chips to be tested in the test tray T is located at the loading position 2a.

Accordingly, the first loading picker 221 may contain new packaged chips to be tested in the loading buffer 23 while the second loading picker 222 containing the packaged chips to be tested in the test tray T is located at the loading position 2a. As a result, the time for the loading process may be further reduced and efficiency of the loading process may be further enhanced.

As shown in FIG. 3D, the loading buffer 23 may transfer the packaged chips to be tested to another containing area L that is adjacent to a containing area L′ where the second loading picker 222 contains the packaged chips to be tested in the test tray T located at the loading position 2a.

The second loading picker 222 may pick up the packaged chips to be tested from the loading buffer 23, move to the corresponding containing area L′ by the predetermined distance 222a, and then contain the packaged chips in the test tray T located at the loading position 2a.

As described above, the loading buffer 23 may transfer the packaged chips contained therein to the containing area L, L′ or M that is most adjacent to the containing area L, L′ or M where the second loading picker 222 contains the packaged chips to be tested.

When the containing area L, L′ or M where the second loading picker 222 contains the packaged chips to be tested in the test tray T located at the loading position changes, the loading buffer 23 may transfer the packaged chips to be tested to the containing area L, L′ or M that is most adjacent to the corresponding containing area L, L′, or M.

Accordingly, regardless of positions of the containing areas L, L′ and M, a distance by which the second loading picker 222 moves to perform the loading process may be reduced.

Another example where the loading buffer 23 and the loading picker 22 operate may now be described with reference to FIGS. 4A to 4D.

The loading buffer 23 may move along the loading moving path A to transfer the packaged chips to be tested to the containing area where the second loading picker 222 contains the packaged chips to be tested in the test tray T located at the loading position 2a.

As shown in FIG. 4A, when the loading buffer 23 is located in the area (i.e., the area B) between the user tray located in the loading stacker 21 and the loading position 2a, the first loading picker 221 may provide the packaged chips to be tested to the loading buffer 23. After the packaged chips to be tested are contained in the loading buffer 23, the loading buffer 23 may move along the loading moving path A.

As shown in FIG. 4B, the loading buffer 23 may transfer the packaged chips to be tested to the containing area M where the second loading picker 222 contains the packaged chips to be tested in the test tray T located at the loading position 2a.

As shown in FIG. 4C, when the second loading picker 222 picks up the packaged chips to be tested from the loading buffer 23, the loading buffer 23 moves to the area (i.e., the area B) between the user tray located in the loading stacker 21 and the loading position 2a.

When the loading buffer 23 departs from the containing area M, the second loading picker 222 may move to the containing area M and contain the packaged chips to be tested in the test tray T located at the loading position 2a.

Accordingly, the second loading picker 222 may move by a lesser distance when the loading buffer 23 is located in the area (i.e., the area B) between the user tray located in the loading stacker 21 and the loading position 2a and thereby perform the loading process. As a result, the time for the loading process may be reduced.

The first loading picker 221 may contain new packaged chips to be tested in the loading buffer 23 while the second loading picker 222 contains the packaged chips in the test tray T located at the loading position 2a. As a result, the time for the loading process may be further reduced and efficiency of the loading process may be further enhanced.

As shown in FIG. 4D, when the loading process is finished in the corresponding containing area M, the second loading picker 222 may move to a different containing area L adjacent thereto.

Thereafter, the loading buffer 23 may transfer the packaged chips to be tested to an area above a containing area L that is different than where the second loading picker 222 contains the packaged chips to be tested in the test tray T located at the loading position 2a.

When the second loading picker 222 picks up the packaged chips to be tested from the loading buffer 23, the loading buffer 23 may move to the area (i.e., area B) between the user tray located in the loading stacker 21 and the loading position 2a. When the loading buffer 23 departs from the containing area L, the second loading picker 222 may move to the containing area L and contain the packaged chips in the test tray T located at the loading position 2a.

As described above, the loading buffer 23 may transfer the packaged chips to be tested to an area above the containing area M or L where the second loading picker 222 contains the packaged chips in the test tray T located at the loading position 2a.

That is, when the containing area M or L where the second loading picker 222 contains the packaged chips in the test tray T located at the loading position is changed, the loading buffer 23 may transfer the packaged chips to the corresponding containing area M or L.

Accordingly, regardless of positions of the containing areas M and L, a distance by which the second loading picker 222 moves to perform the loading process may be reduced.

As shown in FIGS. 5 and 6, the loading unit 2 may further include a first loading ascending/descending system 24.

The first loading ascending/descending system 24 may allow the test tray T to ascend and descend along a first ascending/descending path E formed among the loading position 2a, a first arriving position 2b, and a first departing position 2c. The loading position 2a, the first arriving position 2b, and the first departing position 2c may be arranged sequentially from top to bottom (in a direction of arrow N) along the first ascending/descending path E.

The first arriving position 2b may be an arrival position of the test tray T transferred from the unloading unit 3. The test tray T transferred from the unloading unit 3 may be a test tray T subjected to the unloading process and that waits at the first arriving position 2b before moving to the loading position 2a.

The first departing position 2c may be a position where the test tray T subjected to the loading process may depart for a rotating unit. The test tray T having been subjected to the loading process may wait at the first departing position 2c before moving to the rotating unit. The first departing position 2c may be flush (or substantially level) with the rotating unit.

The first loading ascending/descending system 24 may include a first ascending/descending member 241 and a first driving unit 242.

The first loading ascending/descending member 241 may support the test tray T and may ascend and descend along the first ascending/descending path E based on operations of the first driving unit 242. The first loading ascending/descending member 241 may contact a bottom of the test tray T to support the test tray T.

The first loading ascending/descending member 241 may be formed open in the direction (i.e., a direction of arrow P in FIG. 6) from the loading unit 2 to the unloading unit 3. Accordingly, the test tray T may be transferred from the first departing position 2c to the passage site 4 and the test tray T may be transferred from the unloading unit 3 to the first arriving position 2b without interference with the first ascending/descending member 241.

The first driving unit 242 may allow the first ascending/descending member 241 to ascend and descend along the first ascending/descending path E. The first ascending/descending member 241 can ascend and descend among the loading position 2a, the first arriving position 2b, and the first departing position 2c based on the first driving unit 242.

The first driving unit 242 may include a plurality of cylinders and rods that move based on the cylinders. The first ascending/descending member 241 may be coupled to the rods and can ascend and descend based on the movement of the rods by the cylinders. The cylinders may be hydraulic cylinders or pneumatic cylinders, for example.

Referring to FIG. 1, the unloading unit 3 may perform the unloading process and may be disposed (or provided) aside the loading unit 2. The unloading unit 3 may include an unloading stacker 31, an unloading picker 32 and an unloading buffer 33.

The unloading stacker 31 may store a plurality of user trays containing tested packaged chips. The tested packaged chips may be contained in different user trays located at different positions by grades in the unloading stacker 31 based on the test result.

The unloading picker 32 may perform the unloading process on the test tray T. The test tray T may be located at an unloading position 3a at a time of separating the tested packaged chips contained therein from the test tray T.

The unloading picker 32 may move in (or along) the X axis direction and the Y axis direction and can ascend and descend. The unloading picker 32 may include nozzles for sucking and attaching (or fixing) to the packaged chips. The unloading picker 32 may include a first unloading picker 321 and a second unloading picker 322.

The first unloading picker 321 may pick up the tested packaged chips from the unloading buffer 33 and contain the picked-up packaged chips in the user tray located in the unloading stacker 31. The test handler 1 may include a plurality of first unloading pickers 321. The first unloading picker 321 contains the packaged chips picked up from the unloading buffer 33 in a user tray corresponding to the grade based on the test result.

The first unloading picker 321 may pick up at least one tested packaged chip from the unloading buffer 33 and contain the picked-up packaged chip in the user tray located in the unloading stacker 31. The first unloading picker 321 may pick up a plurality of tested packaged chips (in the unit of a matrix) from the unloading buffer 33 at a same time and may contain the picked-up packaged chips in the user tray located in the unloading stacker 31 (in the unit of the matrix).

The second unloading picker 322 may separate the tested packaged chips from the test tray T located at the unloading position 3a and provide the separated packaged chips to the unloading buffer 33.

The second unloading picker 322 may partition the test tray T located at the unloading position 3a into a plurality of separation areas and contain the tested packaged chips in the separation areas.

The separation area may be in the form of a matrix formed by the packaged chips that can be separated from the test tray at a same time by the second unloading picker 322. That is, the separation area in the form of a matrix formed by the packaged chips may be sucked and attached at a same time by the second unloading picker 322.

The second unloading picker 322 can separate the tested packaged chips from the test tray T located at the unloading position 3a (in the unit of the matrix) at a same time. The second unloading picker 322 can contain the tested packaged chips in the unloading buffer 33 (in the unit of the matrix) at a same time. The second unloading picker 322 can contain the separated packaged chips in the unloading buffer 33 corresponding to the grade based on the test result.

Referring to FIGS. 1 and 2, the unloading buffer 33 may move in or along the Y axis direction and may temporarily contain the tested packaged chips. The test handler 1 may include at least one unloading buffer 33.

Although not shown, the unloading buffer 33 may be coupled to a belt that connects and moves a plurality of pulleys when a motor rotates at least one pulley. When the test handler 1 includes a plurality of unloading buffer 33, the unloading buffers 33 may each move individually.

Referring to FIGS. 7 and 8A, the unloading buffer 33 may move along an unloading moving path F formed over the unloading position 3a.

The unloading buffer 33 may move along the unloading moving path F to a position where the first unloading picker 321 can pick up the tested packaged chips from the unloading buffer 33.

The unloading buffer 33 may move along the unloading moving path F to a position where the second unloading picker 322 can contain the tested packaged chips in the unloading buffer 33.

The unloading buffer 33 may be movably coupled to an unloading guide rail 33a to guide the unloading buffer 33 along the unloading moving path F.

The test handler 1 may include a plurality of unloading buffers 33 that each move individually. When the test handler 1 includes a plurality of unloading buffers, the time for the unloading process may be reduced and efficiency of the unloading process may be enhanced. Since the first unloading picker 321 and the second unloading picker 322 may operate on different unloading buffers 33, the operating areas may not overlap with each other, thereby reducing a waiting time.

However, as the test handler 1 includes a greater number of unloading buffers 33, a width 1H (i.e., a length in the X axis direction in FIG. 1) of the test handler 1 may also become greater. When the width 1H of the test handler 1 becomes greater, distances by which the first unloading picker 321 and the second unloading picker 322 move to perform the unloading process may also become greater.

Accordingly, when the test handler 1 includes a plurality of unloading buffers 33, at least one unloading buffer may move along the unloading moving path F and pass over the test tray T located at the unloading position 3a.

Even when the test handler 1 includes a large number of unloading buffers 33, the width 1H of the test handler 1 can be embodied in a same length or a minimum-increased length.

Therefore, since distances by which the first unloading picker 321 and the second unloading picker 322 move to perform the unloading process may be reduced and a waiting time may be reduced, a time for the unloading process may be reduced and efficiency of the unloading process may be enhanced.

As shown in FIG. 7, one of the plurality of unloading buffers 33 may move so that a part thereof passes over the test tray T located at the unloading position 3a. Although not shown, at least one of the plurality of unloading buffers 33 may move so that an entire portion thereof passes over the test tray T located at the unloading position 3a, similar to the loading buffer 23.

The unloading buffers, other than the at least one unloading buffer 33 moving to pass over the test tray T located at the unloading position 3a, may move along the loading moving path F between the loading position 2a and the unloading position 3a.

The unloading buffers 33 may contain the packaged chips by grades based on the test result. The second unloading picker 322 may separately contain the packaged chips separated from the test tray T located at the unloading position 3a in the unloading buffers 33 corresponding to the grades based on the test result.

As the test handler 1 includes a greater number of unloading buffers 33, the waiting time of the unloading picker 32 may be further reduced. Accordingly, the time for the unloading process may be reduced and efficiency of the unloading process may be enhanced.

An example may now be described of when the unloading buffers 33 and the unloading pickers 32 operate when at least one of the plurality of unloading buffers 33 move to pass over the test tray T located at the unloading position 3a, similar to the loading buffers 23.

Since at least one of the plurality of unloading buffers 33 moves to pass over the test tray T located at the unloading position 3a, a distance by which the second unloading picker 322 moves to perform the unloading process may be reduced. That is, the unloading buffers 33 can move along the unloading moving path F to reduce the distance by which the second unloading picker 322 moves to perform the unloading process. Therefore, the time for the unloading process may be reduced and efficiency of the unloading process may be enhanced.

An example of the unloading buffer 33 and the unloading picker 32 operating may now be described with reference to FIGS. 8A to 8D.

As shown in FIG. 8A, the unloading buffer 33 may move along the unloading moving path F to locate the tested packaged chips in a different separation area S that is adjacent to a separation area R where the second unloading picker 322 separates the tested packaged chips from the test tray T located at the unloading position 3a.

As shown in FIG. 8B, the second unloading picker 322 may move by a predetermined distance 322a to the unloading buffer 33 in the different separation area S and then contain the tested packaged chips in the unloading buffer 33.

Accordingly, the distance by which the second unloading picker 322 moves to perform the unloading process may be reduced and a time for the unloading process may be reduced.

As shown in FIG. 8C, the unloading buffer 33 may move along the unloading moving path F up to an area (i.e., an area G) between the user tray located in the unloading stacker 31 and the unloading position 3a. The first unloading picker 321 may pick up the tested packaged chips from the unloading buffer 33.

As shown in FIG. 8D, the first unloading picker 321 may contain the packaged chips picked up from the unloading buffer 33 in the user tray located in the unloading stacker 31. The unloading buffer 33 may move along the unloading moving path F up to a different separation area U that is adjacent to the separation area S where the second unloading picker 322 separates the tested packaged chips from the test tray T located at the unloading position 3a.

Thereafter, the second unloading picker 322 may move by a predetermined distance 322a up to the area above the unloading buffer 33 located in the different separation area U and then contain the tested packaged chips in the unloading buffer 33.

As described above, the unloading buffer 33 can move to the separation area S or U that is most adjacent to the separation areas R and S where the second unloading picker 322 separates the tested packaged chips.

That is, when the separation area R or S where the second unloading picker 322 separates the tested packaged chips from the test tray T located at the unloading position is changed, the unloading buffer 33 can move to the separation area S or U that is most adjacent to the corresponding separation areas R and S.

Therefore, regardless of positions of the separation areas R, S and U, the distance by which the second unloading picker 322 moves to perform the unloading process may be reduced.

Another example of the unloading buffer 33 and the unloading picker 32 operating may now be described with reference to FIGS. 9A to 9D.

As shown in FIG. 9A, the second unloading picker 322 may separate the tested packaged chips contained in the separation area R from the test tray T located at the unloading position 3a.

As shown in FIG. 9B, the unloading buffer 33 may move along the unloading moving path F up to an area below the second unloading picker 322 having separating the tested packaged chips from the test tray T located at the unloading position 3a.

That is, the unloading buffer 33 is located above the separation area R where the second unloading picker 322 separates the tested packaged chips from the test tray T located at the unloading position 3a.

As show in FIG. 9C, when the second unloading picker 322 contains the tested packaged chips in the unloading buffer 33, the unloading buffer 33 may move along the unloading moving path F up to the area (i.e., the area G) between the user tray located in the unloading stacker 31 and the unloading position 3a.

The first unloading picker 321 may then pick up the tested packaged chips from the unloading buffer 33. The second unloading picker 321 may move to the different separation area S that is adjacent to the separation area R. The second unloading picker 321 may separate the tested packaged chips contained in the corresponding separation area S from the test tray T located at the unloading position 3a.

As shown in FIG. 9D, the first unloading picker 321 contains the packaged chips picked up from the unloading buffer 33 in the user tray located in the unloading stacker 31. The unloading buffer 33 may move along the unloading moving path F up to the area below the second unloading picker 322 having separated the tested packaged chips from the test tray T located at the unloading position 3a.

That is, the unloading buffer 33 may be located above the separation area S where the second unloading picker 322 separates the tested packaged chips from the test tray T located at the unloading position 3a.

As described above, when the separation areas R and S where the second unloading picker 322 separates the tested packaged chips from the test tray T located at the unloading position 3a are changed, the unloading buffer 33 may move to the areas above the corresponding separation areas R and S.

Therefore, regardless of positions of the separation areas R and S, the distance by which the second unloading picker 322 moves to perform the unloading process may be reduced.

As shown in FIGS. 5 and 6, the unloading unit 3 may further include a second ascending/descending unit 34.

The second ascending/descending unit 34 may allow the test tray T to ascend and descend along a second ascending/descending path J formed among the unloading position 3a, a second departing position 3b, and a second arriving position 3c. The unloading position 3a, the second departing position 3b, and the second arriving position 3c may be sequentially arranged from top to bottom (i.e., in a direction of arrow N) in the second ascending/descending path J.

The second departing position 3b may be a position where the test tray T subjected to the unloading process may depart for the first arriving position 2b. The test tray T subjected to the unloading process may wait at the second departing position 3b before being transferred to the first arriving position 2b. The second departing position 3b and the first arriving position 2b may be flush (or substantially level or even) with each other.

The second arriving position 3c may be an arrive position of the test tray T transferred from the passage site 4. The test tray transferred from the passage site 4 may be a test tray T containing the tested packaged chips and that waits at the second arriving position 3c before being transferred for the unloading position 3a. The second arriving position 3c may be flush (or substantially level or even) with the passage site 4 and the first departing position 2c.

The second ascending/descending unit 34 may include a second ascending/descending member 341 and a second driving unit 342.

The second ascending/descending member 341 may support the test tray T and may ascend and descend along the second ascending/descending path J based on the second driving unit 342. The second ascending/descending member 341 may contact a bottom of the test tray T to support the test tray T.

The second ascending/descending member 341 may be formed in the direction (i.e., an opposite direction of arrow F in FIG. 6) from the unloading unit 3 to the loading unit 2. Accordingly, the test tray T may be transferred from the second departing position 3b to the first arriving position 2b and may be transferred from the passage site 4 to the second arriving position 3c without interference with the second ascending/descending member 341.

The second driving unit 342 may allow the second ascending/descending member 341 to ascend and descend along the second ascending/descending path J. The second ascending/descending member 341 may ascend and descend among the unloading position 3a, the second departing position 3b, and the second arriving position 3c based on the second driving unit 342.

The second driving unit 342 may include a plurality of cylinders and rods that move based on the cylinders. The second ascending/descending member 341 may be coupled to the rods to ascend and descend by allowing the cylinders to move the rods.

The test handler 1 may perform the loading process and the unloading process on the test trays T located at different positions and the loading process and the unloading process may be simplified. Accordingly, an error occurrence frequency may be reduced in the loading process and the unloading process and one process of the loading process and the unloading process can be normally performed even when an error occurs in the other process. Therefore, efficiency of the loading process and the unloading process may be enhanced.

By allowing the test tray T to ascend and descend in the loading unit 2 and in the unloading unit 3, a length 1L, shown in FIG. 1, of the test handler 1 may be reduced.

Referring to FIGS. 1 and 10, the passage site 4 may be located between the loading unit 2 and the unloading unit 3. The passage site 4 may connect the loading unit 2 and the unloading unit 3 to the chamber system 5.

The test tray T containing the packaged chips to be tested can be transferred from the loading unit 2 to the chamber system 5 through the passage site 4. The test tray T containing the tested packaged chips can be transferred from the chamber system 5 to the unloading unit 3 through the passage site 4.

Although not shown, the passage site 4 may be provided with a plurality of pulleys, a belt that connect the pulleys, and transferring means coupled to the belt to transfer the test tray T by pushing and pulling the test tray T. The transferring means may be disposed (or provided) in the chamber system 5.

The passage site 4 can be provided between the first departing position 2c and the second arriving position 3c. The passage site 4 may be flush (or substantially level or even) with the first departing position 2c and the second arriving position 3c.

The passage site 4 may further include a rotating unit 41 that rotates the test tray T. The passage site 4 may include a plurality of rotating units 41.

The rotating unit 41 may rotate the test tray T transferred from the loading unit 2 from a horizontal posture (or horizontal position) to a vertical posture (or vertical position). The test tray T rotated to the vertical posture by the rotating unit 41 may be transferred to the chamber system 5.

The rotating unit 41 may rotate the test tray T transferred from the chamber system 5 from the vertical posture to the horizontal posture. The test tray T rotated to the horizontal posture by the rotating unit 41 may be transferred to the unloading unit 3.

Accordingly, the test handler 1 can perform the loading process and the unloading process on the test tray T having the horizontal posture and can perform the testing process on the test tray T having the vertical posture.

Referring to FIGS. 1 and 10, the chamber system 5 disposed in the test handler 1 may include a first chamber 51, a second chamber 52, and a third chamber 53 for the tester to test packaged chips under environments of high temperature, low temperature and normal temperature.

The first chamber 51 may adjust the packaged chips contained in the test tray T transferred from the passage site 4 to a first temperature. The first temperature may be in a temperature range of the packaged chips when the packaged chips are tested by the tester.

The first chamber 51 may include at least one of an electric heater and a liquefied nitrogen injecting apparatus to adjust the packaged chips to be tested to the first temperature. The first chamber 51 can allow the test tray T having the vertical posture to move therein.

When the packaged chips to be tested are adjusted to the first temperature, the test tray T may be transferred from the first chamber 51 to the second chamber 52.

The second chamber 52 may connect the packaged chips adjusted to the first temperature and contained in the test tray T to the hi-fix board H. The second chamber 52 may include a contact unit 521 that connects the packaged chips adjusted to the first temperature to the hi-fix board H, where a part or all of the hi-fix board H is inserted into the contact unit 521. The tester may test the packaged chips to determine electrical characteristics of the packaged chips connected to the hi-fix board H.

The second chamber 52 may include at least one of an electric heater and a liquefied nitrogen injecting apparatus to maintain the packaged chips to be tested at the first temperature. The test handler 1 may include a plurality of second chambers 52 and a hi-fix board H may be separately disposed in each of the second chambers 52.

When the packaged chips are completely tested, the test tray T may be transferred from the second chamber 52 to the third chamber 53.

The third chamber 53 may adjust the tested packaged chips contained in the test tray T to a second temperature. The second temperature may be in a temperature range including the normal temperature or a temperature close to the normal temperature. The third chamber 53 may include at least one of an electric heater and a liquefied nitrogen injecting apparatus to restore the tested packaged chips to the second temperature. The third chamber 53 may allow the test tray T having the vertical posture to move therein.

When the tested packaged chips are adjusted to the second temperature, the test tray T may be transferred from the third chamber 53 to the passage site 4.

As shown in FIG. 10, the first chamber 51, the second chamber 52 and the third chamber 53 may be arranged in the horizontal direction. A plurality of the second chambers 52 may be vertically stacked.

Although not shown, the first chamber 51, the second chamber 52 and the third chamber 53 may be vertically stacked. In this case, the first chamber 51 may be disposed above the second chamber 52 and the third chamber 53 may be disposed below the second chamber 52.

The transferring unit 6 shown in FIGS. 11-12 may transfer the test tray T from the loading unit 2 to the passage site 4, transfer the test tray T from the passage site 4 to the unloading unit 3, and transfer the test tray T from the unloading unit 3 to the loading unit 2. The transferring unit 6 may include a first transferring unit 61 and a second transferring unit 62.

Referring to FIGS. 10 and 11, the first transferring unit 61 may transfer the test tray T located at the first departing position 2c to the passage site 4 and transfer the test tray T located in the passage site 4 to the second arriving position 3c.

The test tray T transferred from the first departing position 2c to the passage site 4 contains the packaged chips to be tested, and the test tray T transferred from the passage site 4 to the second arriving position 3c contains the tested packaged chips.

The first transferring unit 61 may include a first transferring member 611, a second transferring member 612 and a moving member 613.

The first transferring member 611 may transfer the test tray T located at the first departing position 2c to the passage site 4. The first transferring member 611 may push and transfer the test tray T located at the first departing position 2c.

The second transferring member 612 may transfer the test tray T located in the passage site 4 to the second arriving position 3c. The second transferring member 612 may push and transfer the test tray T located in the passage site 4.

The second transferring member 612 may push and transfer the test tray T. Accordingly, even when the test tray T waits at the second arriving position 3c, the second transferring member 612 can move to the original position. As a result, since the second transferring member 612 can move to the position for transferring the next test tray T without a waiting time (or without substantial waiting time), the time when the next test tray T waits in the passage site 4 may be reduced.

Therefore, the waiting time of the test tray T may be reduced by efficiently transferring the test tray T and thus the time for the loading process and the unloading process may be reduced.

The first transferring member 611 and the second transferring member 612 may each be coupled to the moving member 613. The moving member 613 can transfer the test tray T located at the first departing position 2c and the test tray T located in the passage site 4 at a same time by allowing the first transferring member 611 and the second transferring member 612 to move at the same time.

The first transferring member 611 and the second transferring member 612 can be coupled to the moving member 613 with a predetermined gap therebetween so as to provide the first and second transferring members 611, 612 into contact with the test tray T. Although not shown, the moving member 613 can be coupled to a belt that connects the plurality of pulleys rotated by a motor and can move based on movement of the belt.

Referring to FIGS. 10 and 12, the second transferring unit 62 may transfer the test tray T located at the second departing position 3b to the first arriving position 2b. The test tray T transferred from the second departing position 3b to the first arriving position 2b may be a test tray T that is getting empty based on separating the tested packaged chips therefrom in the unloading process.

The second transferring unit 62 may include a third transferring member 621 for pushing and transferring the test tray T. The third transferring member 621 may be coupled to a belt that connects a plurality of pulleys that are rotated by a motor to move with movement of the belt.

The third transferring member 621 may push and transfer the test tray T. Accordingly, even when the test tray T waits at the first arriving position 2b, the third transferring member 621 can move to the original position. As a result, since the third transferring member 621 can move to the position for transferring the next test tray T without a waiting time (or substantial waiting time), the time when the next test tray T waits at the second departing position 3b may be reduced.

Therefore, the waiting time of the test tray T may be reduced by efficiently transferring the test tray T and thus reducing the time for the loading process and the unloading process.

A method for unloading packaged chips according to an example embodiment of the present invention will now be described in detail with reference to the accompanying drawings.

Referring to FIGS. 1-12, the method for unloading packaged chips may have the following configurations.

The second unloading picker 322 may separate the tested packaged chips from the test tray T located at the unloading position 3a. The second unloading picker 322 can separate the tested packaged chips contained in the separation area R from the test tray T located at the unloading position 3a.

At least one of the plurality of unloading buffers 33 may move along the unloading moving path F up to the area above the test tray T located at the unloading position 3a. The unloading buffer 33 can move along the unloading moving path F to partially or entirely pass over the test tray T located at the unloading position 3a.

The second unloading picker 322 may contain the tested packaged chips in the unloading buffer 33. The second unloading picker 322 can contain only the packaged chips, the test result of which is a grade corresponding to the unloading buffer 33, in the unloading buffer 33.

The unloading buffer 33 containing the tested packaged chips may move along the unloading moving path F to the position where the first unloading picker 321 can pick up the tested packaged chips from the unloading buffer 33. The unloading buffer 33 can be located in the area (i.e., the area G) between the user tray located in the unloading stacker 31 and the unloading position 3a.

The first unloading picker 321 may pick up the tested packaged chips from the unloading buffer 33 and contain the picked-up packaged chips in the user tray located in the unloading stacker 31. The first unloading picker 321 can contain the tested packaged chips in the user trays corresponding to the grades based on the test result.

Referring to FIGS. 8A to 8D, allowing the second unloading picker 322 to contain the tested packaged chips in the unloading buffer 33 may further include the following configurations.

The second unloading picker 322 may move to the position above the unloading buffer 33. The unloading buffer 33 may move along the unloading moving path F up to a different separation area S that is most adjacent to the separation area R where the second unloading picker 322 separates the tested packaged chips from the test tray T located at the unloading position 3a.

The second unloading picker 322 may contain the tested packaged chips in the unloading buffer 33.

The second unloading picker 322 may contain the tested packaged chips in the unloading buffer 33 moving over the separation area S or U that is most adjacent to the separation area R or S where the tested packaged chips are separated from the test tray T located at the unloading position 3a based on the separation area R or S.

Accordingly, regardless of positions of the separation areas R, S and U, the distance by which the second unloading picker 322 moves to perform the unloading process may be reduced.

Referring to FIGS. 9A to 9D, transferring at least one of the plurality of unloading buffers 33 along the unloading moving path F up to the position above the test tray T located at the unloading position 3a may include the following configurations.

At least one of the plurality of unloading buffers 33 may move to the position below the second unloading picker 322 that separates the tested packaged chips from the test tray T located at the unloading position 3a.

That is, the unloading buffer 33 may be located above the separation area R where the second unloading picker 322 separates the tested packaged chips from the test tray T located at the unloading position 3a.

As described above, when the separation areas R or S where the second unloading picker 322 separates the tested packaged chips from the test tray T located at the unloading position 3a is changed, the unloading buffer 33 may move to the position above the corresponding separation area R or S.

Accordingly, regardless of the positions of the separation areas R and S, the distance by which the second unloading picker 322 moves to perform the unloading process may be reduced.

A method for transferring test trays according to an example embodiment of the present invention may now be described in detail with reference to the accompanying drawings.

Referring to FIGS. 1 to 12, the method for transferring test trays according to an example embodiment of the present invention may include the following configurations.

The loading unit 2 may perform the loading process of containing the packaged chips to be tested in the test tray T located at the loading position 2a. As described above, the loading picker 22 and the loading buffer 23 may operate according to the example shown in FIGS. 3A to 3D or according to another example shown in FIGS. 4A to 4D, thereby constituting the loading process.

The test tray T having been subjected to the loading process may descend from the loading position 2a to the first departing position 2c below the loading position 2a. The test tray T may descend based on the first ascending/descending unit 24.

The test tray T located at the first departing position 2c may transfer to the passage site 4 that connects the loading unit 2 and the chamber system 5 to each other. The test tray T can be transferred by the first transferring unit 61.

The test tray T located in the passage site 4 and subjected to the loading process may be transferred from the passage site 4 to the chamber system 5. The test tray T may be transferred from the passage site 4 to the first chamber 51 by the transferring means (not shown) provided in the passage site 4 or the chamber system 5.

When the passage site 4 includes the rotating unit 41, the test tray T may be rotated from the horizontal posture to the vertical posture by the rotating unit 41 and may then be transferred from the passage site 4 to the chamber system 5.

In the chamber system 5, the packaged chips in the test tray T may be adjusted to the first temperature, the packaged chips adjusted to the first temperature may be connected to and tested by the hi-fix board H, and the tested packaged chips may be adjusted to the second temperature.

In the course of transferring the test tray T to the first chamber 51, the second chamber 52, and the third chamber 53, the packaged chips may be adjusted to the first temperature by the first chamber 51, the packaged chips adjusted to the first temperature may be connected and tested by the hi-fix board H by the second chamber 52, and the tested packaged chips may be adjusted to the second temperature by the third chamber 53.

The test tray T containing the tested packaged chips may be transferred from the chamber system 5 to the passage site 4. The test tray T may be transferred from the third chamber 53 to the passage site 4 by the transferring means (not shown) provided in the passage site 4 or the chamber system 5.

When the passage site 4 includes the rotating unit 41, the test tray T may be rotated from the vertical posture to the horizontal posture by the rotating unit 41 and may then be transferred from the chamber system 5 to the passage site 4.

The test tray T located in the passage site 4 and containing the tested packaged chips may be transferred from the passage site 4 to the second arriving position 3c below the unloading position 3a. The test tray T can be transferred by the first transferring unit 61.

The transferring of the test tray T located in the passage site 4 and containing the tested packaged chips from the passage site 4 to the second arriving position 3c may be performed at a same time as transferring the test tray T located at the first departing position 2c to the passage site 4. The test trays T can be transferred at the same time by the first transferring unit 61.

The test tray T located at the second arriving position 3c may ascend to the unloading position 3a. The test tray T may ascend by the second ascending/descending unit 34.

The unloading process may be performed on the test tray T located at the unloading position 3a by use of the method for unloading packaged chips. As described above, the unloading picker 32 and the unloading buffer 33 may operate according to the example shown in FIGS. 8A to 8D or according to another example shown in FIGS. 9A to 9D, thereby constructing the unloading process.

The test tray T having been subjected to the unloading process may be transferred from the unloading position 3a to the loading position 2a via the second departing position 3b and the first arriving position 2b. The test tray T may descend from the unloading position 3a to second departing position 3b by the second ascending/descending unit 34, may be transferred from the second departing position 3b to the first arriving position 2b by the second transferring unit 62, and may ascend from the first arriving position 2b to the loading position 2a by the first ascending/descending unit 24.

A method for manufacturing packaged chips according to an example embodiment of the present invention may have a configuration similar to the method for transferring test trays. The detailed description thereof may be omitted for ease of description.

Additionally, the packaged chips to be tested may be prepared. The packaged chips to be tested can be prepared by storing a user tray containing the packaged chips in the loading stacker 21. The packaged chips may include memory or non-memory packaged chips.

By repeatedly performing the above-described processes, manufacturing of the packaged chips may be completed.

Embodiments may provide a test handler and a method for unloading packaged chips that is capable of performing a loading process and an unloading process on a greater number of packaged chips for a short amount of time.

A method may be provided for transferring test trays that is capable of reducing a waiting time of a test tray by efficiently transferring the test tray and reducing a time for the loading process and the unloading process.

A method may be provided for manufacturing packaged chips that is capable of manufacturing more packaged chips for a short amount of time by reducing a time for the loading process and the unloading process, thereby strengthening competitive power of products such as cost reduction.

According to an example embodiment of the invention, a test handler may be provided that includes a loading unit having a loading picker performing a loading process on a test tray located at a loading position (which is a position of the test tray at the time of containing packaged chips to be tested in the test tray). A chamber system may receive the packaged chips contained in the test tray from the loading unit and may connect the chips to a hi-fix board to allow testing. An unloading unit may include at least one unloading buffer moving along an unloading moving path formed over a test tray located at an unloading position (which is a position of the test tray at a time of separating the tested packaged chips from the test tray) and an unloading picker performing an unloading process on the test tray located at the unloading position, the unloading unit being provided aside the loading unit. A passage site may be provided between the loading unit and the unloading unit and may connect the loading unit and the unloading unit to the chamber system so as to transfer the test tray containing the packaged chips to be tested from the loading unit to the chamber system and to transfer the test tray containing the tested packaged chips from the chamber system to the unloading unit. A transferring unit may transfer the test tray from the loading unit to the passage site, transfer the test tray from the passage site to the unloading unit, and transfer the test tray from the unloading unit to the loading unit.

A method may be provided for unloading packaged chips. The method may include allowing a second unloading picker to separate tested packaged chips from a test tray located at an unloading position (which is a position where the test tray is located at a time of separating the tested packaged chips from the test tray). The method may also include allowing at least one of a plurality of unloading buffers to move along an unloading moving path formed over the test tray located at the unloading position so that the at least one unloading buffer is located above the test tray at the unloading position. The method may further include allowing the second unloading picker to contain the tested packaged chips in the unloading buffer, allowing the unloading buffer containing the tested packaged chips to move along the unloading moving path to a position where a first unloading picker can pick up the tested packaged chips from the unloading buffer, and allowing the first unloading picker to pick up the tested packaged chips from the unloading buffer and to contain the picked-up in a user tray located in an unloading stacker.

According to another embodiment, a method may be provided for transferring test trays. The method may include allowing a loading unit to perform a loading process of containing packaged chips to be tested in a test tray located at a loading position (which is defined as a position where the test tray is located at the time of containing the packaged chips to be tested in the test tray). The method may also include allowing the test tray having been subjected to the loading process to descend from the loading position to a first departing position below the loading position. Still further, the method may include transferring the test tray located at the first departing position to a passage site connecting the loading unit and a chamber system, transferring the test tray located in the passage site from the passage site to the chamber system, and allowing the chamber system to adjust the packaged chips contained in the test tray to a first temperature, to connect and test the packaged chips adjusted to the first temperature to a hi-fix board, and to adjust the tested packaged chips to a second temperature. The method may also include transferring the test tray containing the tested packaged chips from the chamber system to the passage site, transferring the test tray located in the passage site and containing the tested packaged chips from the passage site to a first arriving position located below an unloading position (which is a position where the test tray is located at the time of separating the tested packaged chips from the test tray), allowing the test tray located at the first arriving position to ascend to the unloading position, performing an unloading process on the test tray located at the unloading position, and transferring the test tray having been subjected to the unloading process from the unloading position to the loading position through a second departing position (between the unloading position) and the second arriving position and a first arriving position (between the loading position and the first departing position).

According to another embodiment, a method may be provided for manufacturing packaged chips. The method may include preparing packaged chips to be tested, allowing a loading unit to perform a loading process of containing the prepared packaged chips in a test tray located at a loading position (which is a position where the test tray is located at the time of containing the packaged chips to be tested in the test tray), and allowing the test tray having been subjected to the loading process to descend from the loading position to a first departing position below the loading position. The method may also include transferring the test tray located at the first departing position to a passage site connecting the loading unit and a chamber system, transferring the test tray located in the passage site from the passage site to the chamber system, and allowing the chamber system to adjust the packaged chips contained in the test tray to a first temperature, to connect and test the packaged chips adjusted to the first temperature to a hi-fix board, and to adjust the tested packaged chips to a second temperature. The method may also include transferring the test tray containing the tested packaged chips from the chamber system to the passage site, transferring the test tray located in the passage site and containing the tested packaged chips from the passage site to a first arriving position located below an unloading position (which is a position where the test tray is located at the time of separating the tested packaged chips from the test tray) allowing the test tray located at the first arriving position to ascend to the unloading position, performing an unloading process on the test tray located at the unloading position, and transferring the test tray having been subjected to the unloading process from the unloading position to the loading position through a second departing position (between the unloading position and the second arriving position) and a first arriving position (between the loading position and the first departing position).

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A test handler comprising:
a loading unit having a loading picker to perform a loading process on a test tray located at a loading position, the loading position corresponding to a position of the test tray at a time of providing packaged chips to be tested in the test tray;
a chamber system to receive the packaged chips contained in the test tray from the loading unit, to connect the packaged chips to a hi-fix board for testing of the packaged chips;
an unloading unit having at least one unloading buffer and an unloading picker, the unloading buffer to move along an unloading moving path formed over a test tray located at an unloading position, the unloading position corresponding to a position of the test tray at a time of separating the tested packaged chips from the test tray, the unloading picker to perform an unloading process on the test tray located at the unloading position, wherein the unloading unit is provided aside the loading unit;
a passage site between the loading unit and the unloading unit, the passage site to connect the loading unit to the chamber system for transferring the test tray from the loading unit to the chamber system and to connect the chamber system to the unloading unit for transferring the test tray from the chamber system to the unloading unit; and
a transferring unit to transfer the test tray from the loading unit to the passage site, to transfer the test tray from the passage site to the unloading unit, and to transfer the test tray from the unloading unit to the loading unit.

2. The test handler according to claim 1, wherein the unloading unit includes a plurality of unloading buffers each to move individually,
wherein at least one of the plurality of unloading buffers to move along the unloading moving path and to pass over the test tray located at the unloading position

3. The test handler according to claim 1, wherein the loading unit includes at least one loading buffer to move along a loading moving path formed over the test tray located at the loading position.

4. The test handler according to claim 3, wherein the at least one loading buffer to move along the loading moving path and to pass over the test tray located at the loading position.

5. The test handler according to claim 1, wherein the loading unit includes a first ascending/descending unit to move the test tray along a first ascending/descending path that includes the loading position, a first arriving position located below the loading position, and a first departing position located below the first arriving position,
wherein the unloading unit includes a second ascending/descending unit to move the test tray along a second ascending/descending path that includes the unloading position, a second departing position located below the unloading position, and a second arriving position located below the second departing position.

6. The test handler according to claim 5, wherein the transferring unit includes:
a first transferring unit to transfer the test tray at the first departing position to the passage site and to transfer the test tray at the passage site to the second arriving position; and
a second transferring unit to transfer the test tray at the second departing position to the first arriving position.

7. The test handler according to claim 6, wherein the first transferring unit includes:
a first transferring member to transfer the test tray at the first departing position to the passage site;
a second transferring member to transfer the test tray at the passage site to the second arriving position; and
a moving member to couple to the first transferring member and the second transferring member and to allow the first transferring member and the second transferring member to move at a substantially same time.

8. The test handler according to claim 1, wherein the unloading picker includes:
a first unloading picker to pick up tested packaged chips from the unloading buffer and provide the picked-up packaged chips to a user tray located in the unloading stacker; and
a second unloading picker to separate the tested packaged chips from the test tray located at the unloading position and provide the separated packaged chips to the unloading picker, and
wherein the second unloading picker to partition the test tray located at the unloading position into a plurality of separation areas and to separate the tested packaged chips based on the separation areas.

9. The test handler according to claim 8, wherein the at least one unloading buffer to move along the unloading moving path such that a moving distance of the second unloading picker decreases when the second unloading picker performs the unloading process.

10. The test handler according to claim 1, wherein the unloading unit includes a plurality of unloading buffers that each move individually,
wherein at least one of the plurality of unloading buffers to move along the unloading moving path and to pass over the test tray located at the unloading position, and
wherein the other unloading buffers to move along the unloading moving path between the loading position and the unloading position.

11. A method for unloading packaged chips having a first unloading picker and a second unloading picker, the method comprising:
separating tested packaged chips, using the second unloading picker, from a test tray located at an unloading position, the unloading position being a position where the test tray is located at a time of separating the tested packaged chips from the test tray;
moving an unloading buffer along an unloading moving path formed over the test tray located at the unloading position such that the unloading buffer is located above the test tray at the unloading position;
providing the tested packaged chips to the unloading buffer;
moving the unloading buffer containing the tested packaged chips along the unloading moving path to another position; and
picking up the tested packaged chips from the unloading buffer using the first unloading picker and providing the picked-up packaged chips to a user tray located in an unloading stacker.

12. The method according to claim 11, wherein moving the unloading buffer along the unloading moving path includes moving the unloading buffer such that the unloading buffer is located below the second unloading picker having separated the tested packaged chips from the test tray located at the unloading position.

13. The method according to claim 11, wherein providing the tested packaged chips to the unloading buffer includes:
moving the second unloading picker such that the second unloading picker is located above the unloading buffer; and
providing the tested packaged chips to the unloading buffer by using the second unloading picker.

14. A method comprising:
performing a loading process of providing packaged chips to be tested to a test tray located at a loading position, the loading position being a position where the test tray is located at a time of containing the packaged chips to be tested in the test tray;
moving the test tray from the loading position to a first departing position below the loading position;
transferring the test tray located at the first departing position to a passage site that connects the loading unit and a chamber system;
transferring the test tray from the passage site to the chamber system;
adjusting the packaged chips contained in the test tray to a first temperature, connecting the packaged chips adjusted to the first temperature to a hi-fix board for testing the packaged chips, and adjusting the tested packaged chips to a second temperature;
transferring the test tray containing the tested packaged chips from the chamber system to the passage site;
transferring the test tray from the passage site to an arriving position located below an unloading position, the unloading position being a position where the test tray is located at the time of separating the tested packaged chips from the test tray;
moving the test tray from the arriving position to the unloading position;
performing an unloading process on the test tray at the unloading position; and
transferring the test tray subjected to the unloading process from the unloading position to the loading position by passing through a second departing position and another arriving position, the second departing position being between the unloading position and the arriving position, and the another arriving position between the loading position and the first departing position.

15. The method according to claim 14, wherein performing the unloading process includes:
separating the tested packaged chips from the test tray located at the unloading position using a second unloading picker;
moving an unloading buffer along an unloading moving path formed over the test tray located at the unloading position such that the unloading buffer is located above the test tray at the unloading position;
providing the tested packaged chips to the unloading buffer;
moving the unloading buffer containing the tested packaged chips along the unloading moving path to a position where a first unloading picker picks up the tested packaged chips from the unloading buffer; and
picking up the tested packaged chips from the unloading buffer using the first unloading picker and providing the picked-up to a user tray located in an unloading stacker.

16. The method according to claim 15, wherein moving the unloading buffer along the unloading moving path includes moving the unloading buffer such that the unloading buffer is located below the second unloading picker having separated the tested packaged chips from the test tray located at the unloading position.

17. The method according to claim 15, wherein providing the tested packaged chips to the unloading buffer includes:
moving the second unloading picker such that the second unloading picker is located above the unloading buffer; and
providing the tested packaged chips to the unloading buffer by using the second unloading picker.

18. The method according to claim 14, wherein transferring the test tray located at the first departing position to the passage site is performed at a same time as transferring the test tray from the passage site to the arriving position located below the unloading position.

19. The method according to claim 14, further comprising:
preparing packaged chips to be tested prior to performing the loading process.
